(19) United States
(12) Patent Application Publication
(10) Pub. No.: US 2025/0149341 A1
(43) Pub. Date: May 8, 2025

(54) METHOD FOR PROCESSING LAMINATED WAFER

(71) Applicant: DISCO CORPORATION, Tokyo (JP)

(72) Inventors: Kokichi MINATO, Tokyo (JP); Atsushi KOMATSU, Tokyo (JP); Koichi MAKINO, Tokyo (JP); Hironobu OZAWA, Tokyo (JO)

(21) Appl. No.: 18/929,998

(22) Filed: Oct. 29, 2024

(30) Foreign Application Priority Data
Nov. 7, 2023 (JP) 2023-189782

(51) Int. Cl. H01L 21/304

(52) U.S. Cl. CPC H01L 21/304

(57) ABSTRACT

A method is for processing a laminated wafer in which a front surface side of a first wafer having an outer peripheral edge chamfered in an arc shape and a front surface side of a second wafer are joined. The method includes: removing a chamfered portion by applying an external force to the chamfered portion of the first wafer and separating the chamfered portion from the first wafer; and grinding another surface side opposite to the one surface side of the first wafer after removing the chamfered portion.

### CROSS-REFERENCE TO RELATED APPLICATION(S)

The present application claims priority to and incorporates by reference the entire contents of Japanese Patent Application No. 2023-189782 filed in Japan on Nov. 7, 2023.

### BACKGROUND

The present disclosure relates to a method for processing a laminated wafer.

In recent years, in order to improve a signal processing speed of a semiconductor chip or the like, a semiconductor substrate having a three-dimensional laminated structure has been put into practical use. The semiconductor substrate as described above is manufactured, for example, from a laminated wafer formed by bonding a first semiconductor wafer and a second semiconductor wafer with an adhesive or the like.

Specifically, after the back surface side of the first semiconductor wafer is ground and thinned, the first semiconductor wafer is divided into individual device chips by a dicing apparatus or the like.

However, since the outer peripheral portion of the semiconductor wafer is chamfered, when the back surface side of the first semiconductor wafer is ground and thinned, the outer periphery of the wafer becomes a so-called knife edge, and edge chipping occurs during grinding.

As a countermeasure against such chipping, a method has been proposed in which edge trimming is performed on a chamfered portion of a first semiconductor wafer before grinding to remove the chamfered portion (see, for example, JP 2005-116614 A).

However, in the method described in JP 2005-116614 A, there is a possibility that the cutting blade cuts into the front surface side of the second wafer in the edge trimming step of removing the chamfered portion of the first wafer, leading to deterioration of quality.

### SUMMARY

A method according to one aspect of the present disclosure is for processing a laminated wafer in which one surface side of a first wafer having an outer peripheral edge chamfered in an arc shape and one surface side of a second wafer are joined together. The method includes: removing a chamfered portion by applying an external force to the chamfered portion of the first wafer and separating the chamfered portion from the first wafer; and grinding another surface side opposite to the one surface side of the first wafer after removing the chamfered portion.

### BRIEF DESCRIPTION OF THE DRAWINGS

FIG. 1 is a cross-sectional view schematically illustrating a configuration example of a laminated wafer to be processed by a method for processing a laminated wafer according to a first embodiment;

FIG. 2 is a flowchart illustrating a flow of the method for processing the laminated wafer according to the first embodiment;

FIG. 3 is a perspective view illustrating a configuration example of a cutting apparatus that performs a holding step, a chamfered portion weak step, and a chamfered portion removing step of the method for processing the laminated wafer illustrated in FIG. 2;

FIG. 4 is a side view schematically illustrating the holding step of the method for processing the laminated wafer illustrated in FIG. 2 in a partial cross section;

FIG. 5 is a side view schematically illustrating the chamfered portion weakening step of the method for processing the laminated wafer illustrated in FIG. 2 in a partial cross section;

FIG. 6 is a cross-sectional view schematically illustrating a main part of the laminated wafer after the chamfered portion weakening step of the method for processing the laminated wafer illustrated in FIG. 2;

FIG. 7 is a cross-sectional view schematically illustrating a main part of a modification of the laminated wafer illustrated in FIG. 6;

FIG. 8 is a side view schematically illustrating the chamfered portion removing step of the method for processing the laminated wafer illustrated in FIG. 2 in a partial cross section;

FIG. 9 is a cross-sectional view schematically illustrating a state in which a chamfered portion is removed in the chamfered portion removing step of the method for processing the laminated wafer illustrated in FIG. 2 in a partial cross section;

FIG. 10 is a side view schematically illustrating a modification of the chamfered portion removing step of the method for processing the laminated wafer illustrated in FIG. 2 in a partial cross section;

FIG. 11 is a cross-sectional view schematically illustrating a state in which the thickness between a bottom of a stepped portion and a functional layer is measured in the chamfered portion removing step of the method for processing the laminated wafer illustrated in FIG. 2 in a partial cross section;

FIG. 12 is a cross-sectional view schematically illustrating a state in which the stepped portion reaches the functional layer in the chamfered portion removing step of the method for processing the laminated wafer illustrated in FIG. 2 in a partial cross section;

FIG. 13 is a side view schematically illustrating a grinding step of the method for processing the laminated wafer illustrated in FIG. 2 in a partial cross section;

FIG. 14 is a side view schematically illustrating a chamfered portion removing step of a method for processing a laminated wafer according to a second embodiment in a partial cross section;

FIG. 15 is a cross-sectional view schematically illustrating a state in which a chamfered portion is removed in the chamfered portion removing step of the method for processing the laminated wafer according to the second embodiment in a partial cross section;

FIG. 16 is a side view schematically illustrating a chamfered portion removing step of a method for processing a laminated wafer according to a modification of the second embodiment in a partial cross section;

FIG. 17 is a side view schematically illustrating a chamfered portion removing step of a method for processing a laminated wafer according to a third embodiment in a partial cross section;

FIG. 18 is a cross-sectional view schematically illustrating a state in which a chamfered portion is removed in the chamfered portion removing step of the method for processing the laminated wafer according to the third embodiment in a partial cross section;

FIG. 19 is a side view schematically illustrating a chamfered portion removing step of a method for processing a laminated wafer according to a modification of the third embodiment in a partial cross section;

FIG. 20 is a cross-sectional view schematically illustrating a state in which a chamfered portion is removed in the chamfered portion removing step of the method for processing the laminated wafer according to the modification of the third embodiment in a partial cross section;

FIG. 21 is a side view schematically illustrating a chamfered portion removing step of a method for processing a laminated wafer according to a fourth embodiment in a partial cross section;

FIG. 22 is a cross-sectional view schematically illustrating a state in which a chamfered portion is removed in the chamfered portion removing step of the method for processing the laminated wafer according to the fourth embodiment in a partial cross section;

FIG. 23 is a side view schematically illustrating a chamfered portion removing step of a method for processing a laminated wafer according to a fifth embodiment in a partial cross section; and

FIG. 24 is a cross-sectional view schematically illustrating a state in which a chamfered portion is removed in the chamfered portion removing step of the method for processing the laminated wafer according to the fifth embodiment in a partial cross section.

### DETAILED DESCRIPTION

Modes (embodiments) for carrying out the present disclosure will be described in detail with reference to the drawings. The present invention is not limited by the contents described in the following embodiments. In addition, the components described below include those that can be easily assumed by those skilled in the art and those that are substantially the same. Furthermore, the configurations described below can be appropriately combined. In addition, various omissions, substitutions, or changes in the configuration can be made without departing from the gist of the present invention.

### First Embodiment

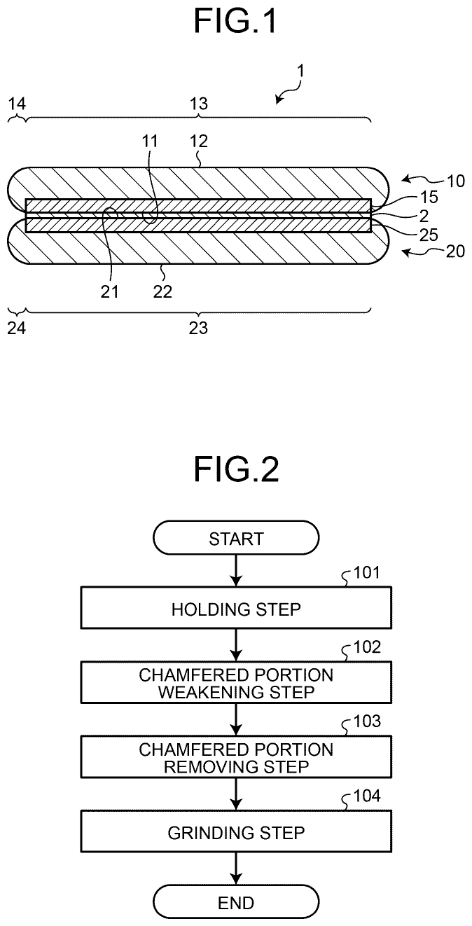

A method for processing a laminated wafer according to a first embodiment of the present disclosure will be described with reference to the drawings. FIG. 1 is a cross-sectional view schematically illustrating a configuration example of a laminated wafer to be processed by the method for processing the laminated wafer according to the first embodiment. FIG. 2 is a flowchart illustrating a flow of the method for processing the laminated wafer according to the first embodiment.

### Workpiece

The method for processing the laminated wafer according to the first embodiment is a method for processing a laminated wafer 1 illustrated in FIG. 1. In the first embodiment, the laminated wafer 1 to be processed by the method for processing the laminated wafer includes a first wafer 10 and a second wafer 20. In the first embodiment, the first wafer 10 and the second wafer 20 are wafers such as disk-shaped semiconductor wafers using silicon, gallium arsenide, silicon carbide (SiC), or the like as a substrate. Note that, in the first embodiment, the first wafer 10 and the second wafer 20 have the same configuration.

As illustrated in FIG. 1, in the first wafer 10 and the second wafer 20, a plurality of planned division lines intersecting (orthogonally in the first embodiment) front surfaces 11 and 21 (corresponding to one surface) is set, and devices are formed in a plurality of regions defined by the planned division lines. The device is, for example, an integrated circuit such as an integrated circuit (IC) or a large scale integration (LSI), or various memories (semiconductor storage apparatuses).

The laminated wafer 1 is formed by joining the front surface 11 side of the first wafer 10 and the front surface 21 side of the second wafer 20. In addition, in the first embodiment, the front surface 11 side of the first wafer 10 and the front surface 21 side of the second wafer 20 are joined by an adhesive layer 2 formed of an adhesive or the like. In the laminated wafer 1, the wafers 10 and 20 are divided along the planned division lines and singulated into individual device chips having a so-called three-dimensional laminated structure.

In addition, in the first embodiment, each of the first wafer 10 and the second wafer 20 includes disk-shaped disk portions 13 and 23 having flat front surfaces 11 and 21 parallel to each other and back surfaces 12 and 22 (corresponding to the other surface) on the opposite sides of the front surfaces 11 and 21, and chamfered portions 14 and 24 formed integrally with the disk portions 13 and 23 at the outer edges of the disk portions 13 and 23. The chamfered portions 14 and 24 are formed from the front surfaces 11 and 21 to the back surfaces 12 and 22, and are formed in an arcuate cross section such that the center in the thickness direction is located on the outermost peripheral side.

In this way, in the first embodiment, the first wafer 10 and the second wafer 20 are chamfered in an arc shape at the outer peripheral edge by providing the chamfered portions 14 and 24. In the laminated wafer 1 according to the first embodiment, the disk portion 13 of the first wafer 10 and the disk portion 23 of the second wafer 20 are joined to each other, and the chamfered portions 14 and 24 are not joined to each other (that is, they are spaced apart without being in contact with each other).

In addition, in the first embodiment, functional layers 15 and 25 are formed at least on the front surfaces 11 and 21 of the disk portions 13 and 23 of the first wafer 10 and the second wafer 20, respectively. The functional layers 15 and 25 include an inorganic film such as SiOF or BSG (SiOB), an organic film which is a polymer film such as a polyimide film or a parylene film, or a low dielectric constant insulator film (hereinafter, referred to as a Low-k film) constituted by carbon-containing silicon oxide (SiOCH), and a circuit layer including a conductive metal pattern and a metal film.

The Low-k film is laminated with the circuit layer to form a device. The circuit layer constitutes a circuit of the device. For this purpose, the device includes a Low-k film of the functional layers 15 and 25 laminated with each other and a circuit layer laminated between the Low-k films. In the planned division lines, the functional layers 15 and 25 are constituted by Low-k films.

### Method for Processing Laminated Wafer

The method for processing the laminated wafer according to the first embodiment is a method for processing the laminated wafer 1 illustrated in FIG. 1. As illustrated in FIG. 2, the method for processing the laminated wafer according to the first embodiment includes a holding step 101, a chamfered portion weakening step 102, a chamfered portion removing step 103, and a grinding step 104.

### Cutting Apparatus

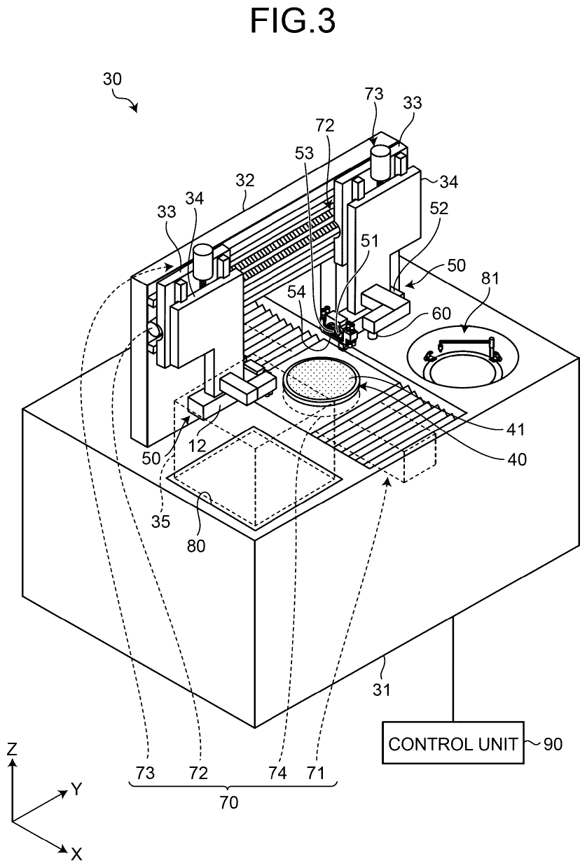

Next, the cutting apparatus 30 that performs the holding step 101, the chamfered portion removing step 103, and the chamfered portion removing step 103 will be described. FIG. 3 is a perspective view illustrating a configuration example of the cutting apparatus that performs the holding step, the chamfered portion weak step, and the chamfered portion removing step of the method for processing the laminated wafer illustrated in FIG. 2.

The cutting apparatus 30 is a processing apparatus that holds the laminated wafer 1 on a holding table 40 and performs cutting processing (corresponding to processing) with a cutting blade 51. As illustrated in FIG. 3, the cutting apparatus 30 includes the holding table 40 that sucks and holds the laminated wafer 1 on a holding surface 41, a cutting unit 50 that performs cutting processing on the laminated wafer 1 held on the holding table 40 with the cutting blade 51, an imaging unit 60 that images the laminated wafer 1 held on the holding table 40, and a control unit 90.

In addition, as illustrated in FIG. 3, the cutting apparatus 30 includes a moving unit 70 that relatively moves the holding table 40 and the cutting unit 50. The moving unit 70 includes at least: an X-axis moving unit 71 which is a machining feed unit for machining and feeding the holding table 40 in the X-axis direction parallel to the horizontal direction; a Y-axis moving unit 72 which is an indexing feed unit for indexing and feeding the cutting unit 50 in the Y-axis direction parallel to the horizontal direction and orthogonal to the X-axis direction; a Z-axis moving unit 73 which is a cutting feed unit for feeding the cutting unit 50 in the Z-axis direction parallel to the vertical direction orthogonal to both the X-axis direction and the Y-axis direction for cutting; and a rotation moving unit 74 for rotating the holding table 40 about an axis parallel to the Z-axis direction.

As illustrated in FIG. 3, the cutting apparatus 30 is a cutting apparatus including two cutting units 50, that is, a two-spindle dicer, that is, a so-called facing dual-type cutting apparatus. The moving unit 70 of the cutting apparatus 30 includes two Y-axis moving units 72 and two Z-axis moving units 73, and the two Y-axis moving units 72 and the two Z-axis moving units 73 correspond to the cutting units 50, respectively.

The X-axis moving unit 71 is installed in an apparatus body 31, and moves the holding table 40 in the X-axis direction, which is the machining feed direction, together with the rotation moving unit 74 to relatively machine feed the holding table 40 and the cutting unit 50 along the X-axis direction. The Y-axis moving unit 72 is installed on a gate-shaped support frame 32 erected from the apparatus body 31, and moves the corresponding cutting unit 50 in the Y-axis direction which is the indexing feed direction to relatively index and feed the holding table 40 and the cutting unit 50 along the Y-axis direction.

The Z-axis moving unit 73 is installed on a moving frame 33 moved in the Y-axis direction by the Y-axis moving unit 72, and relatively feeds the holding table 40 and the cutting unit 50 along the Z-axis direction for cutting by moving the corresponding cutting unit 50 in the Z-axis direction, which is the cutting feed direction.

Each of the X-axis moving unit 71, the Y-axis moving unit 72, and the Z-axis moving unit 73 includes a known ball screw rotatably provided around an axis, a known motor that rotates the ball screw around the axis, and a known guide rail that movably supports the holding table 40 or the cutting unit 50 in the X-axis direction, the Y-axis direction, or the Z-axis direction. The rotation moving unit 74 includes a known motor or the like that rotates the holding table 40 about the axis.

The holding table 40 has a disk shape, and the holding surface 41 for holding the laminated wafer 1 is formed of porous ceramic or the like. In addition, the holding table 40 is provided movably in the X-axis direction over a processing region below the cutting unit 50 by the X-axis moving unit 71 and a loading/unloading region separated from below the cutting unit 50 into which the laminated wafer 1 is loaded and unloaded, and is provided rotatably about an axis parallel to the Z-axis direction by the rotation moving unit 74. In the holding table 40, the holding surface 41 is connected to a vacuum suction source (not illustrated) and sucked by the vacuum suction source to suck and hold the laminated wafer 1 placed on the holding surface 41.

The cutting unit 50 is a processing unit to which the cutting blade 51 for cutting processing the laminated wafer 1 held on the holding table 40 is detachably attached. Each of the cutting units 50 is attached to the second moving frame 34 movable in the Z-axis direction by the corresponding Z-axis moving unit 73, is provided movably in the Y-axis direction by the Y-axis moving unit 72 with respect to the laminated wafer 1 held on the holding table 40, and is provided movably in the Z-axis direction by the Z-axis moving unit 73. In the cutting unit 50, the cutting blade 51 can be positioned at an arbitrary position on the holding surface 41 of the holding table 40 by the Y-axis moving unit 72 and the Z-axis moving unit 73.

The cutting unit 50 includes the cutting blade 51, a spindle housing 52 attached to a lower end of the second moving frame 34 and provided movably in the Y-axis direction and the Z-axis direction by the Y-axis moving unit 72 and the Z-axis moving unit 73, a spindle 53 serving as a rotating shaft rotatably provided in the spindle housing 52 around an axis, a spindle motor (not illustrated) that rotates the spindle 53 around the axis, and a coolant supply nozzle that supplies coolant to the cutting blade.

The cutting blade 51 is an ultrathin cutting grindstone having a substantially ring shape for cutting the laminated wafer 1. In the first embodiment, the cutting blade 51 includes at least an annular cutting edge 54 for cutting the laminated wafer 1. The cutting edge 54 is constituted by abrasive grains such as diamond and cubic boron nitride (CBN) and a bonding material (binder) such as metal and resin, and is formed to have a predetermined thickness. Note that, in the first embodiment, the cutting blade 51 is a so-called washer blade including only the cutting edge 54. However, in the present disclosure, the cutting blade may be a so-called hub blade including an annular base having an annular shape and the cutting edge 54 provided on an outer edge of the annular base.

The spindle housing 52 is attached to the lower end of the second moving frame 34, is movably supported in the Z-axis direction by the Z-axis moving unit 73, and is movably supported in the Y-axis direction by the Y-axis moving unit 72 via the Z-axis moving unit 73 and the moving frame 34. The spindle housing 52 accommodates a portion excluding the tip portion of the spindle 53, a spindle motor (not illustrated), and the like, and supports the spindle 53 so as to be rotatable about the axis.

In the spindle 53, the cutting blade 51 is detachably fixed to the tip. The spindle 53 is rotated by a spindle motor (not illustrated), and the cutting blade 51 is attached to the tip portion. The axes of the spindle 53 and the cutting blade 51 of the cutting unit 50 are parallel to the Y-axis direction.

The imaging unit 60 images the laminated wafer 1 held by the holding table 40 and acquires a captured image. The imaging unit 60 is fixed to the cutting unit 50 so as to move integrally with the cutting unit 50. The imaging unit 60 includes an imaging element that images a region to be subjected to cutting processing of the laminated wafer 1 before the cutting processing, the region being held on the holding table 40. The imaging element is, for example, a charge-coupled device (CCD) imaging element or a complementary MOS (CMOS) imaging element. The imaging unit images the laminated wafer 1 held on the holding table 40, acquires an image for performing alignment for aligning the laminated wafer 1 and the cutting blade 51 or the like, and outputs the acquired image to the control unit 90.

In addition, the cutting apparatus 30 includes an X-axis direction position detection unit (not illustrated) for detecting the position of the holding table 40 in the X-axis direction, a Y-axis direction position detection unit (not illustrated) for detecting the position of the cutting unit 50 in the Y-axis direction, and a Z-axis direction position detection unit for detecting the position of the cutting unit 50 in the Z-axis direction. The X-axis direction position detection unit and the Y-axis direction position detection unit can be configured by a linear scale parallel to the X-axis direction or the Y-axis direction and a reading head. The Z-axis direction position detection unit detects the position of the cutting unit 50 in the Z-axis direction by a pulse of the motor.

The X-axis direction position detection unit, the Y-axis direction position detection unit, and the Z-axis direction position detection unit output the positions of the holding table 40 in the X-axis direction and the cutting unit 50 in the Y-axis direction or the Z-axis direction to the control unit 90. An angle detection unit outputs an angle of the holding table 40 from the reference position about the axis to the control unit 90. Note that, in the first embodiment, the positions of the components of the cutting apparatus 30 in the X-axis direction, the Y-axis direction, and the Z-axis direction are determined based on predetermined reference positions (not illustrated).

In addition, the cutting apparatus 30 includes a cassette elevator 80 that places a cassette 35 containing the laminated wafer 1 before and after cutting and moves the cassette 35 in the Z-axis direction, a cleaning unit 81 that cleans the laminated wafer 1 after cutting processing, and a conveyance unit (not illustrated) that conveys the laminated wafer 1 between the cassette 35, the holding table 40, and the cleaning unit 81.

The control unit 90 also controls each component of the cutting apparatus 30 to cause the cutting apparatus 30 to perform a machining operation on the laminated wafer 1. Note that the control unit 90 is a computer including an arithmetic processing apparatus including a microprocessor such as a central processing unit (CPU), a storage apparatus including a memory such as a read only memory (ROM) or a random access memory (RAM), and an input/output interface apparatus. The arithmetic processing apparatus of the control unit 90 performs arithmetic processing according to a computer program stored in the storage apparatus, and outputs a control signal for controlling the cutting apparatus 30 to each component of the cutting apparatus 30 via the input/output interface apparatus.

The control unit 90 is connected to a display unit (not illustrated) including a liquid crystal display apparatus or the like that displays a state of a machining operation, a captured image, or the like, an input unit (not illustrated) used when an operator registers machining conditions or the like, and a notification unit (not illustrated). The input unit includes at least one of a touch panel provided on the display unit or an external input apparatus such as a keyboard. The notification unit emits at least one of sound or light to notify the operator.

### Holding Step

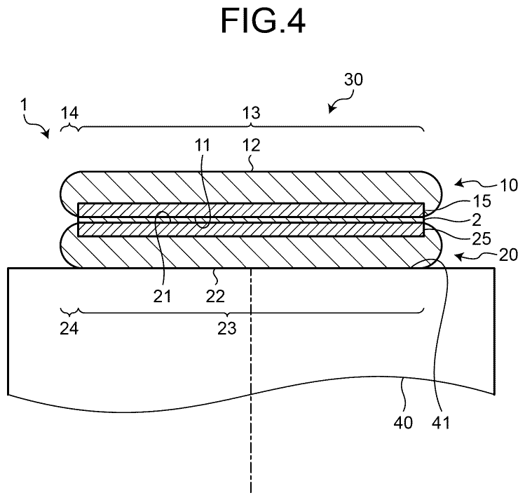

Next, the holding step 101 will be described. FIG. 4 is a side view schematically illustrating the holding step of the method for processing the laminated wafer illustrated in FIG. 2 in a partial cross section. The holding step 101 is a step of holding the laminated wafer 1 on the holding surface 41 of the holding table 40.

In the first embodiment, in the cutting apparatus 30, the cassette 35 containing a plurality of laminated wafers 1 is placed in the cassette elevator 80, and the control unit 90 receives and registers machining conditions input from the input unit or the like by an operator. When the control unit 90 receives a machining start instruction input from the input unit or the like by the operator, the cutting apparatus 30 starts the machining operation, that is, the holding step 101.

In the first embodiment, in the holding step 101, the control unit 90 of the cutting apparatus 30 starts rotation of the spindle 53 of the cutting unit 50, that is, the cutting blade 51, and starts supply of coolant to the cutting blade 51. In the first embodiment, in the holding step 101, the control unit 90 of the cutting apparatus 30 controls the cassette elevator 80, the conveyance unit, and the like to take out one laminated wafer 1 before cutting processing from the cassette 35, and places the back surface 22 side of the second wafer 20 of the laminated wafer 1 on the holding surface 41 of the holding table 40 positioned in the loading/unloading region. In the first embodiment, in the holding step 101, as illustrated in FIG. 4, the control unit 90 of the cutting apparatus 30 sucks and holds the back surface 22 of the second wafer 20 of the laminated wafer 1 on the holding surface 41 of the holding table 40 positioned in the loading/unloading region.

### Chamfered Portion Weakening Step

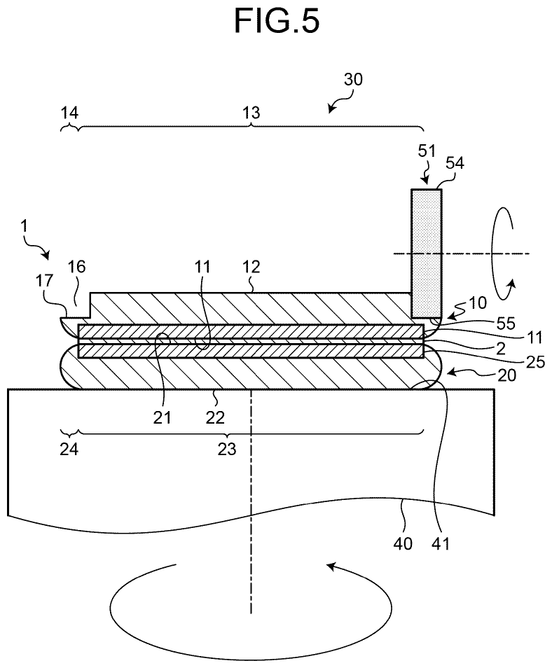

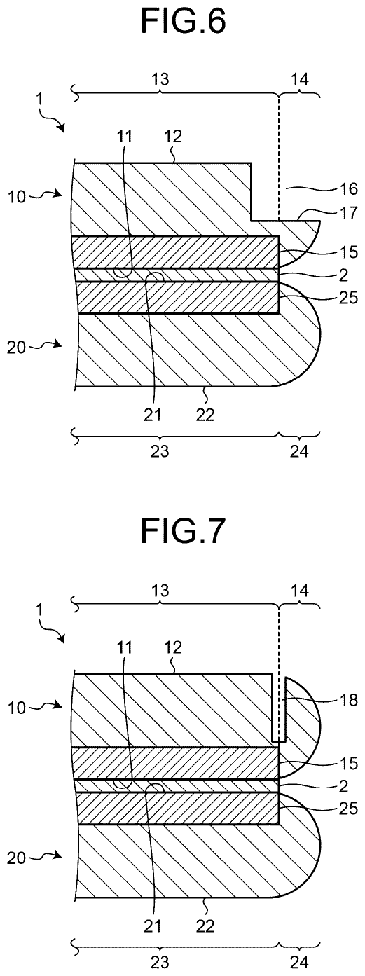

FIG. 5 is a side view schematically illustrating the chamfered portion weakening step of the method for processing the laminated wafer illustrated in FIG. 2 in a partial cross section. FIG. 6 is a cross-sectional view schematically illustrating a main part of the laminated wafer after the chamfered portion weakening step of the method for processing the laminated wafer illustrated in FIG. 2. FIG. 7 is a cross-sectional view schematically illustrating a main part of a modification of the laminated wafer illustrated in FIG. 6. The chamfered portion weakening step 102 is a step of cutting processing (corresponding to grinding) the chamfered portion 14 with the cutting edge 54 of the cutting blade 51 serving as a grindstone to remove a part of the chamfered portion 14 before the chamfered portion removing step 103.

In the first embodiment, in the chamfered portion weakening step 102, the control unit 90 of the cutting apparatus 30 controls the moving unit 70 to position the holding table 40 holding the laminated wafer 1 in the processing region, and causes the imaging unit 60 to image the laminated wafer 1 to perform alignment. In the first embodiment, in the chamfered portion weakening step 102, as illustrated in FIG. 5, the cutting apparatus 30 rotates the holding table 40 about the axis by the rotation moving unit 74 while causing the outer peripheral surface 55 of the cutting edge 54 of the cutting blade 51 rotated about the axis to cut the chamfered portion 14 of the first wafer 10 from the back surface 12 side, and removes the back surface 12 side of the chamfered portion 14 of the first wafer 10 of the laminated wafer 1 over the entire circumference to form the stepped portion 16 on the outer peripheral edge of the first wafer 10.

In the first embodiment, in the chamfered portion weakening step 102, the outer peripheral surface 55 of the cutting edge 54 of the cutting blade 51 thicker than the width of the chamfered portion 14 is cut into the chamfered portion 14 of the first wafer 10 and the outer edge portion of the disk portion 13 from the back surface 12 side, and as illustrated in FIG. 6, the chamfered portion 14 and the outer edge portion (region where the device is not formed yet) of the disk portion 13 are removed from the back surface 12 side of the first wafer 10 of the laminated wafer 1, and the stepped portion 16 is formed with a bottom 17 on the back surface 12 side of the first wafer 10 with respect to the functional layer 15 to weaken the chamfered portion 14. In addition, in the first embodiment, in the chamfered portion weakening step 102, the stepped portion 16 is formed from the outer edge of the first wafer 10 to the outer edge portion of the disk portion 13, and the bottom 17 is formed flat in parallel with the front surface 11 and the back surface 12.

Note that, in the present disclosure, in the chamfered portion weakening step 102, as illustrated in FIG. 7, the outer peripheral surface 55 of the cutting edge 54 of the cutting blade 51 thinner than the width of the chamfered portion 14 may be cut into the boundary between the chamfered portion 14 and the disk portion 13 of the first wafer 10 from the back surface 12 side to form a groove 18 whose bottom is closer to the back surface 12 side of the first wafer 10 than the functional layer 15, thereby weakening the chamfered portion 14.

### Chamfered Portion Removing Step

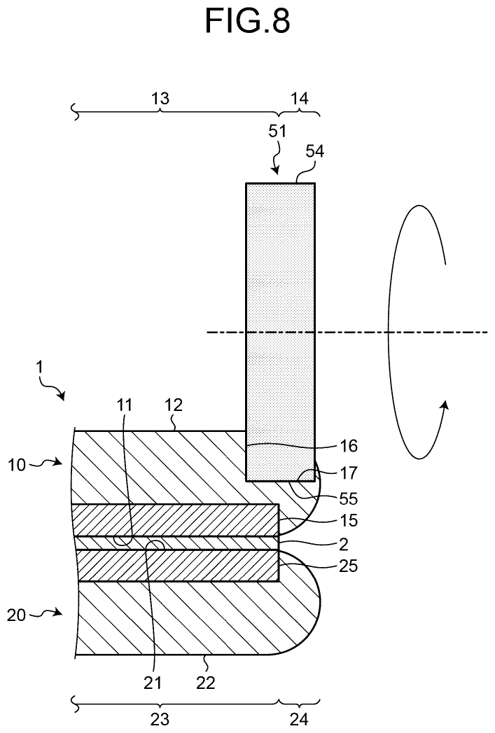

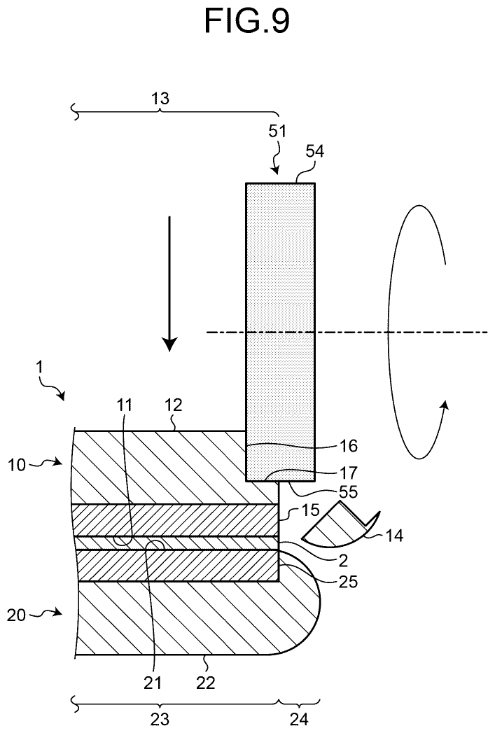

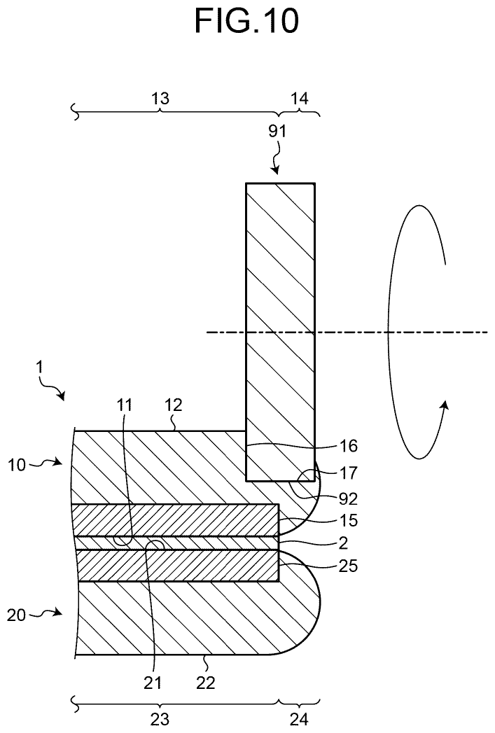

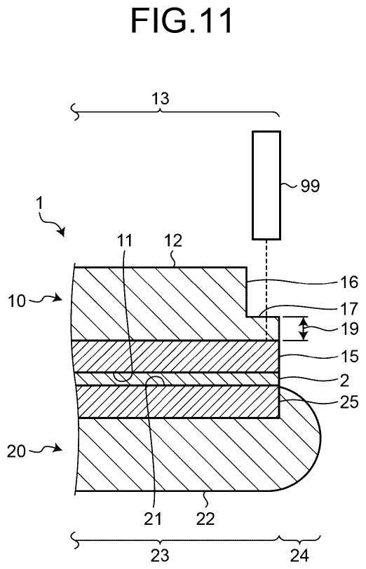

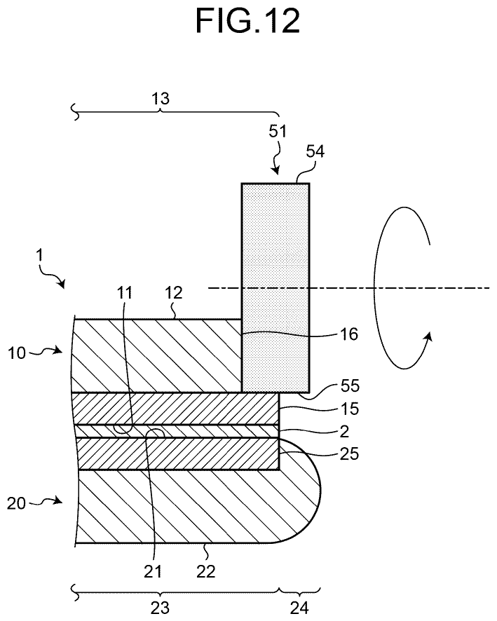

FIG. 8 is a side view schematically illustrating the chamfered portion removing step of the method for processing the laminated wafer illustrated in FIG. 2 in a partial cross section. FIG. 9 is a cross-sectional view schematically illustrating a state in which the chamfered portion is removed in the chamfered portion removing step of the method for processing the laminated wafer illustrated in FIG. 2 in a partial cross section. FIG. 10 is a side view schematically illustrating a modification of the chamfered portion removing step of the method for processing the laminated wafer illustrated in FIG. 2 in a partial cross section. FIG. 11 is a cross-sectional view schematically illustrating a state in which the thickness between the bottom of the stepped portion and the functional layer is measured in the chamfered portion removing step of the method for processing the laminated wafer illustrated in FIG. 2 in a partial cross section. FIG. 12 is a cross-sectional view schematically illustrating a state in which the stepped portion reaches the functional layer in the chamfered portion removing step of the method for processing the laminated wafer illustrated in FIG. 2 in a partial cross section.

The chamfered portion removing step 103 is a step of removing the chamfered portion 14 by applying an external force to the chamfered portion 14 of the first wafer 10 and separating the chamfered portion 14 from the first wafer 10. The chamfered portion removing step 103 is also a step of separating the chamfered portion 14, which is a non-joined region, from the disk portion 13 with a boundary between the chamfered portion 14, which is a non-joined region generated in an arc shape of the chamfered portion 14, and the disk portion 13, which is a joined region, as a starting point. The chamfered portion removing step 103 is also a step of applying an external force to the chamfered portion 14 which is a non-joined region and dividing the first wafer 10 with the boundary between the disk portion 13 and the chamfered portion 14 as a starting point.

In the first embodiment, in the chamfered portion removing step 103, the cutting apparatus 30 positions the outer peripheral surface 55 of the cutting edge 54 of the cutting blade 51 rotating about the axis above the bottom 17 of the stepped portion 16, lowers the cutting blade 51, and rotates the holding table 40 about the axis while performing cutting processing on the bottom 17 of the stepped portion 16 with the outer peripheral surface 55 of the cutting edge 54 of the cutting blade 51 as illustrated in FIG. 8. Then, since the disk portions 13 and 23 are joined to each other and the chamfered portions 14 and 24 are spaced apart from each other, the external force from the cutting edge 54 of the cutting blade 51 concentrates on the boundary between the disk portion 13 and the chamfered portion 14 of the first wafer 10, and the chamfered portion 14 of the first wafer 10 is divided from the disk portion 13 starting from the boundary as illustrated in FIG. 9. As described above, in the first embodiment, in the chamfered portion removing step 103, the chamfered portion 14 of the first wafer 10 is divided from the disk portion 13 starting from the boundary between the disk portion 13 and the chamfered portion 14 of the first wafer 10, so that the cutting blade 51 does not need to be lowered until the chamfered portion 14 of the first wafer 10 is removed. Note that, in the chamfered portion removing step 103, the grinding load may be increased by using the cutting edge 54 of the cutting blade 51 having abrasive grains larger than those in the chamfered portion weakening step 102, gradually increasing the machining feed speed for lowering the cutting blade 51, or the like. That is, in the chamfered portion removing step 103, a cutting blade 51 different from the chamfered portion weakening step 102 may be used.

In addition, machining conditions may be similar to those in chamfered portion weakening step 102, or may be substantially the same as those in chamfered portion removing step 103. In addition, in the chamfered portion removing step 103, when the cutting blade 51 is lowered, an external force may be applied to the boundary of the first wafer 10 by repeating, for example, lowering by 100 um and raising by 10 um a plurality of times.

Thus, in the first embodiment, in the chamfered portion removing step 103, the chamfered portion 14 is subjected to cutting processing by the cutting blade 51 from the back surface 12 side of the first wafer 10, and the chamfered portion 14 is separated from the disk portion 13 of the first wafer 10 by the load at the time of the cutting processing.

Note that, in the first embodiment, in the chamfered portion removing step 103, instead of the cutting blade 51, an outer peripheral surface 92 of a disk-shaped polishing pad 91 rotating about the axis parallel to the Y-axis direction may be positioned above the bottom 17 of the stepped portion 16 of the first wafer 10, the polishing pad 91 may be lowered, and as illustrated in FIG. 10, the holding table 40 may be rotated about the axis while the bottom 17 of the stepped portion 16 is polished by the outer peripheral surface 92 of the polishing pad 91, and the external force from the cutting edge 54 of the cutting blade 51 may be concentrated on the boundary between the disk portion 13 and the chamfered portion 14 of the first wafer 10. As described above, in the first embodiment, in the chamfered portion removing step 103, the chamfered portion 14 may be polished on the outer peripheral surface 92 of the polishing pad 91 from the back surface 12 side of the first wafer 10, and the chamfered portion 14 may be separated from the disk portion 13 of the first wafer 10 by the load at the time of polishing.

In the first embodiment, in the chamfered portion removing step 103, as illustrated in FIG. 11, the cutting apparatus 30 measures the thickness 19 of the substrate at the bottom 17 of the stepped portion 16, that is, the thickness 19 between the bottom 17 and the functional layer by the optical interference type film thickness measuring instrument 99. In the first embodiment, in the chamfered portion removing step 103, the cutting apparatus 30 causes the outer peripheral surface 55 of the cutting edge 54 of the cutting blade 51 to cut into the bottom 17 of the stepped portion 16 to cause the stepped portion 16 to reach the functional layer 15, that is, removes the substrate of the bottom 17 of the stepped portion 16, as illustrated in FIG. 12, on the basis of the thickness 19 measured by the optical interference type film thickness measuring instrument 99. Note that, in the present disclosure, in the chamfered portion removing step 103, the stepped portion 16 may be caused to reach the functional layer 15, that is, the substrate of the bottom 17 of the stepped portion 16 may be removed by etching such as wet etching or dry etching.

### Grinding Step

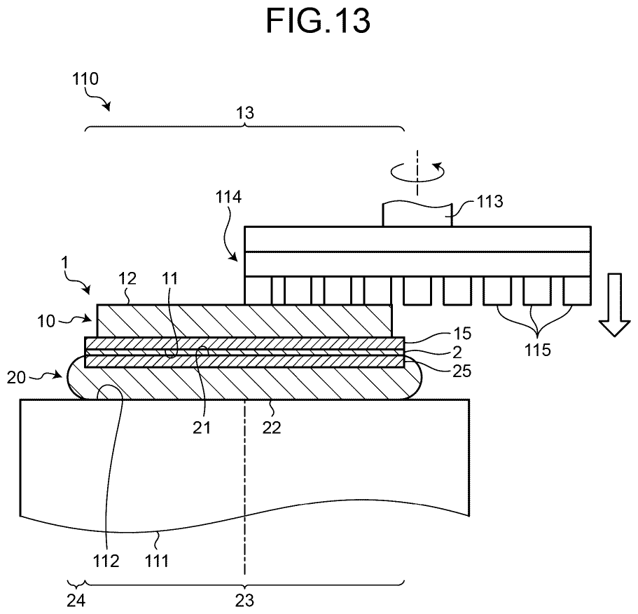

FIG. 13 is a side view schematically illustrating the grinding step of the method for processing the laminated wafer illustrated in FIG. 2 in a partial cross section. The grinding step 104 is a step of grinding the back surface 12 side opposite to the front surface 11 side of the first wafer 10 after the chamfered portion removing step 103.

In the first embodiment, in the grinding step 104, as illustrated in FIG. 13, a grinding apparatus 110 sucks and holds the back surface 22 side of the second wafer 20 of the laminated wafer 1 on a holding surface 112 of a chuck table 111, rotates a grinding wheel 114 by a spindle 113 and rotates the chuck table 111 about the axis, and brings a grinding stone 115 into contact with the back surface 12 of the first wafer 10 of the laminated wafer 1 to approach the chuck table 111 at a predetermined feed speed, thereby grinding the back surface 12 of the first wafer 10 of the laminated wafer 1 with the grinding stone 115. In the first embodiment, in the grinding step 104, the grinding apparatus 110 grinds the first wafer 10 until a predetermined thickness is obtained.

As described above, in the method for processing the laminated wafer according to the first embodiment, after an external force is applied to the chamfered portion 14 of the first wafer 10 to separate the chamfered portion 14 from the disk portion 13 of the first wafer 10 in the chamfered portion removing step 103, the first wafer 10 is ground in the grinding step 104. Therefore, in the method for processing the laminated wafer according to the first embodiment, when the chamfered portion 14 of the first wafer 10 is removed, the cutting blade 51 does not cut the front surface 21 of the second wafer 20.

As a result, the method for processing the laminated wafer according to the first embodiment has an effect that the laminated wafer 1 can be ground and thinned without deteriorating the quality.

In addition, in the method for processing the laminated wafer according to the first embodiment, when the chamfered portion 14 is separated using the polishing pad 91 as illustrated in FIG. 10 in the chamfered portion removing step 103, the outer peripheral surface of the first wafer 10 is polished with the polishing pad 91 after the chamfered portion 14 is separated, so that damage such as cutting strain generated in the chamfered portion weakening step 102 can be removed.

### Second Embodiment

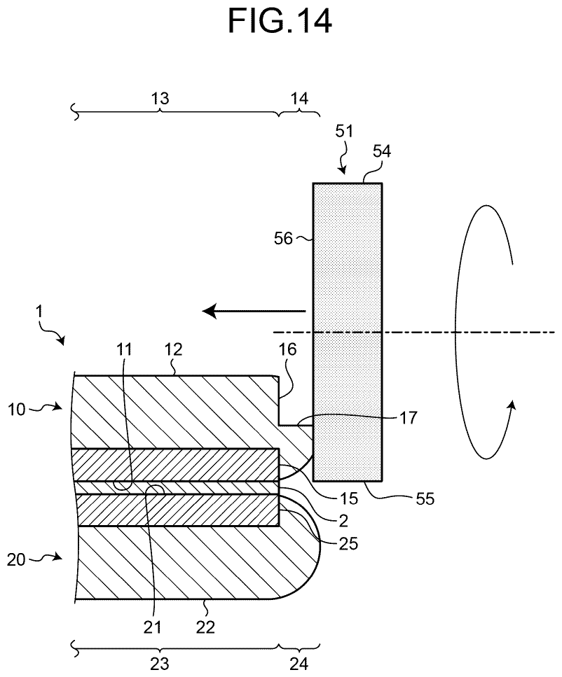

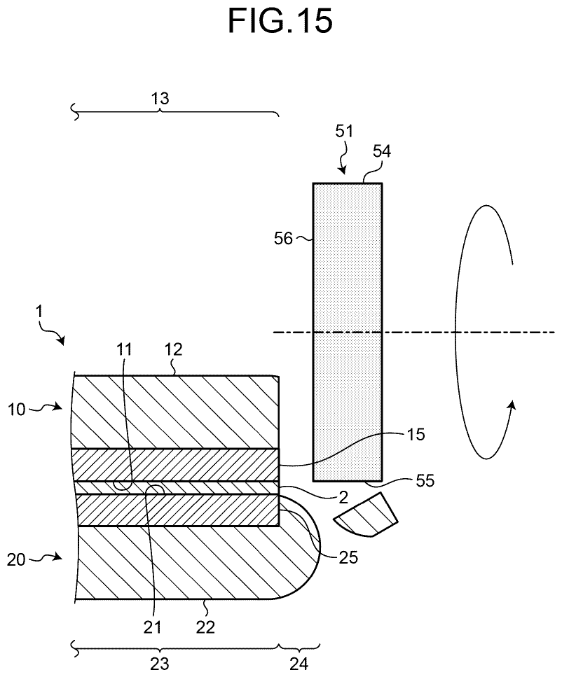

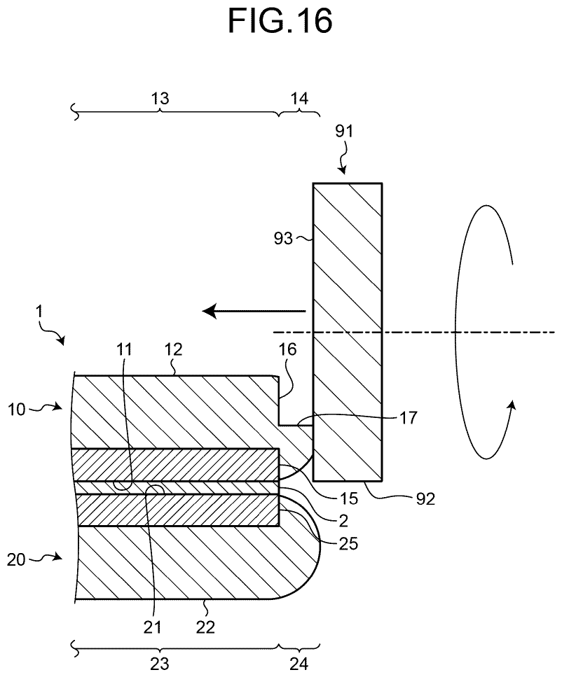

A method for processing a laminated wafer according to a second embodiment will be described with reference to the drawings. FIG. 14 is a side view schematically illustrating the chamfered portion removing step of the method for processing the laminated wafer according to the second embodiment in a partial cross section. FIG. 15 is a cross-sectional view schematically illustrating a state in which the chamfered portion is removed in the chamfered portion removing step of the method for processing the laminated wafer according to the second embodiment in a partial cross section. FIG. 16 is a side view schematically illustrating a chamfered portion removing step of a method for processing a laminated wafer according to a modification of the second embodiment in a partial cross section. Note that, in FIGS. 14, 15, and 16, the same parts as those of the first embodiment are denoted by the same reference signs, and description thereof is omitted.

The method for processing the laminated wafer according to the second embodiment is the same as that of the first embodiment except that the stepped portion 16 is formed only in the chamfered portion 14 of the first wafer 10 in the chamfered portion weakening step 102 and the chamfered portion removing step 103 is different. Note that, in the second embodiment, in the chamfered portion weakening step 102, the stepped portion 16 is formed from the back surface 12 side of the first wafer 10 to the outer edge of the first wafer 10 and the boundary between the disk portion 13 and the chamfered portion 14 of the first wafer 10.

In the second embodiment, in the chamfered portion removing step 103, the cutting apparatus 30 positions the ring-shaped side surface 56 of the cutting edge 54 of the cutting blade 51 rotating about the axis on the outer periphery of the chamfered portion 14 of the first wafer 10, moves the cutting blade 51 in the Y-axis direction, and rotates the holding table 40 about the axis while moving the cutting blade 51 to the inner peripheral side of the first wafer 10 while bringing the side surface 56 of the cutting edge 54 of the cutting blade 51 into contact with the outer edge of the chamfered portion 14 of the first wafer 10 as illustrated in FIG. 14. In the second embodiment, in the chamfered portion removing step 103, the external force from the cutting edge 54 of the cutting blade 51 is concentrated on the boundary between the disk portion 13 and the chamfered portion 14 of the first wafer 10, and the chamfered portion 14 of the first wafer 10 is divided from the disk portion 13 starting from the boundary as illustrated in FIG. 15. As described above, in the second embodiment, in the chamfered portion removing step 103, the chamfered portion 14 is subjected to cutting processing by the cutting edge 54 of the cutting blade 51 from the radially outer side of the first wafer 10, and the chamfered portion 14 is separated from the disk portion 13 of the first wafer 10 by the load at the time of the cutting processing.

Note that, in the second embodiment, in the chamfered portion removing step 103, it is desirable to increase the grinding load by using the cutting edge 54 of the cutting blade 51 having abrasive grains larger than those in the chamfered portion weakening step 102 or by gradually increasing the machining feed speed at which the cutting blade 51 is moved in the Y-axis direction, or the like.

The method for processing the laminated wafer according to the second embodiment applies an external force to the chamfered portion 14 of the first wafer 10 to separate the chamfered portion 14 from the disk portion 13 of the first wafer 10 in the chamfered portion removing step 103, so that the laminated wafer 1 can be ground and thinned without deteriorating the quality similarly to the first embodiment.

In addition, it is conceivable to remove the substrate of the bottom 17 of the stepped portion 16 by conventional edge trimming in order to prevent the knife edge from being formed, and then etching. In this case, there is a possibility that the disk portion 13 of the first wafer 10, that is, the region where the device is formed is also etched at the time of etching.

In contrast to such conventional edge trimming, in the method for processing the laminated wafer according to the second embodiment, the chamfered portion 14 is removed by applying an external force in the chamfered portion removing step 103, so that there is no possibility that the disk portion 13 of the first wafer 10, that is, the region where the device is formed is etched.

Note that, in the second embodiment, instead of the cutting blade 51, a ring-shaped polishing surface 93 of the disk-shaped polishing pad 91 rotating about the axis may be positioned on the outer periphery of the chamfered portion 14 of the first wafer 10, the polishing pad 91 may be moved in the Y-axis direction, and as illustrated in FIG. 16, the holding table 40 may be rotated about the axis while moving the polishing pad 91 toward the inner peripheral side of the first wafer 10 while bringing the polishing surface 93 of the polishing pad 91 into contact with the outer edge of the chamfered portion 14 of the first wafer 10, and the external force from the cutting edge 54 of the cutting blade 51 may be concentrated on the boundary between the disk portion 13 and the chamfered portion 14 of the first wafer 10. As described above, in the second embodiment, in the chamfered portion removing step 103, the chamfered portion 14 may be polished with the polishing pad 91 from the radially outer side of the first wafer 10, and the chamfered portion 14 may be separated from the disk portion 13 of the first wafer 10 by the load at the time of polishing.

In this case, in addition to the effect of the second embodiment described above, since the outer peripheral surface of the first wafer 10 is polished with the polishing pad 91 after the chamfered portion 14 is separated, damage such as cutting strain generated in the chamfered portion weakening step 102 can be removed.

### Third Embodiment

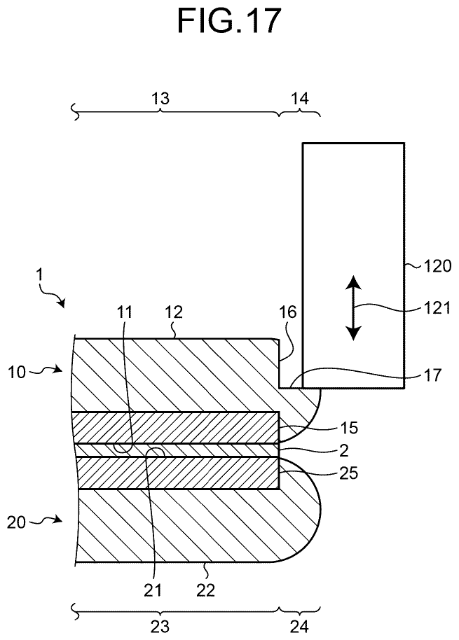

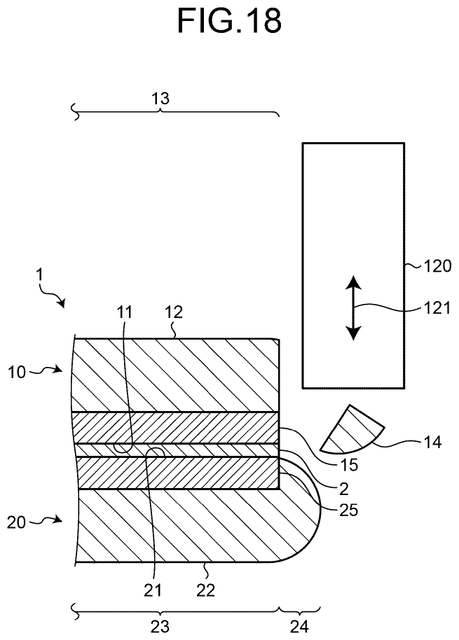

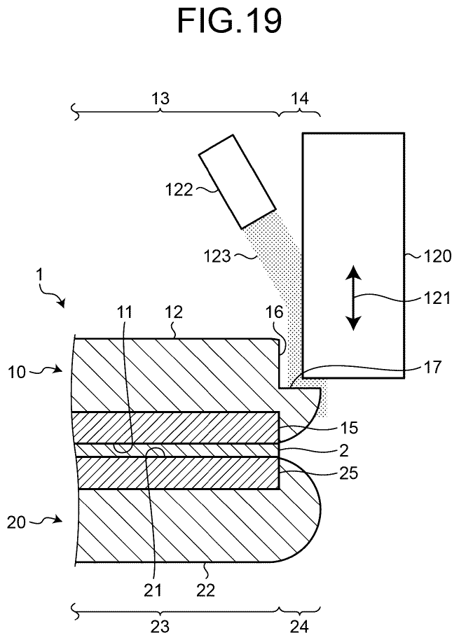

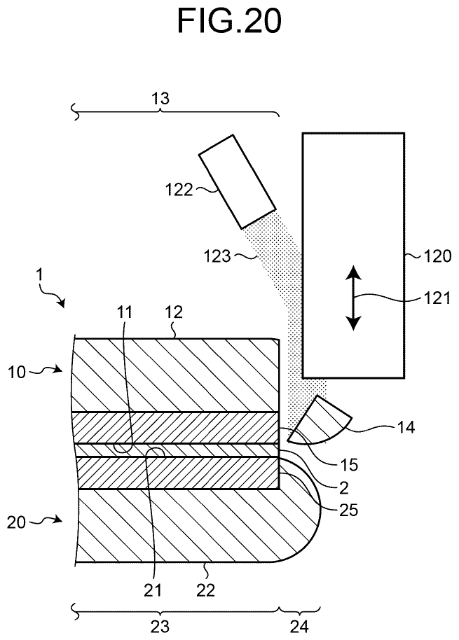

A method for processing a laminated wafer according to a third embodiment will be described with reference to the drawings. FIG. 17 is a side view schematically illustrating the chamfered portion removing step of the method for processing the laminated wafer according to the third embodiment in a partial cross section. FIG. 18 is a cross-sectional view schematically illustrating a state in which the chamfered portion is removed in the chamfered portion removing step of the method for processing the laminated wafer according to the third embodiment in a partial cross section. FIG. 19 is a side view schematically illustrating a chamfered portion removing step of a method for processing a laminated wafer according to a modification of the third embodiment in a partial cross section. FIG. 20 is a cross-sectional view schematically illustrating a state in which the chamfered portion is removed in a chamfered portion removing step of a method for processing a laminated wafer according to a modification of the third embodiment in a partial cross section. Note that, in FIGS. 17, 18, 19, and 20, the same parts as those of the first embodiment are denoted by the same reference signs, and description thereof is omitted.

The method for processing the laminated wafer according to the third embodiment is the same as that of the first embodiment except that the stepped portion 16 is formed only in the chamfered portion 14 of the first wafer 10 in the chamfered portion weakening step 102 and the chamfered portion removing step 103 is different. Note that, in the third embodiment, similarly to the second embodiment, in the chamfered portion weakening step 102, the stepped portion 16 is formed from the back surface 12 side of the first wafer 10 to the outer edge of the first wafer 10 and the boundary between the disk portion 13 and the chamfered portion 14 of the first wafer 10.

In the third embodiment, in the chamfered portion removing step 103, as illustrated in FIG. 17, an ultrasonic vibrator 120 that performs ultrasonic vibration 121 using a piezoelectric element or the like is brought into contact with the bottom 17 of the stepped portion 16 formed from the back surface 12 side on the chamfered portion 14 of the first wafer 10 of the laminated wafer 1. In the third embodiment, in the chamfered portion removing step 103, the external force from the ultrasonic vibration 121 of the ultrasonic vibrator 120 is concentrated on the boundary between the disk portion 13 and the chamfered portion 14 of the first wafer 10, and the chamfered portion 14 of the first wafer 10 is divided from the disk portion 13 starting from the boundary as illustrated in FIG. 18.

In addition, in the third embodiment, in the chamfered portion removing step 103, as illustrated in FIG. 19, the ultrasonic vibrator 120 that ultrasonically vibrates 121 with a piezoelectric element or the like may be made to face the bottom 17 of the stepped portion 16 formed from the back surface 12 side on the chamfered portion 14 of the first wafer 10 of the laminated wafer 1, and liquid 123 may be supplied from a liquid supply nozzle 122 between the ultrasonic vibrator 120 and the bottom 17 of the stepped portion 16. Also in this case, in the chamfered portion removing step 103, the external force from the ultrasonic vibration 121 of the ultrasonic vibrator 120 is concentrated on the boundary between the disk portion 13 and the chamfered portion 14 of the first wafer 10, and the chamfered portion 14 of the first wafer 10 is divided from the disk portion 13 starting from the boundary as illustrated in FIG. 20. Note that, in the case illustrated in FIGS. 19 and 20, the temperature and the type of the liquid 123 are desirably set as appropriate.

As described above, in the third embodiment, in the chamfered portion removing step 103, the chamfered portion 14 is separated from the disk portion 13 of the first wafer 10 by applying the ultrasonic vibration 121 to the chamfered portion 14.

The method for processing the laminated wafer according to the third embodiment applies an external force to the chamfered portion 14 of the first wafer 10 to separate the chamfered portion 14 from the disk portion 13 of the first wafer 10 in the chamfered portion removing step 103, so that the laminated wafer 1 can be ground and thinned without deteriorating the quality similarly to the first embodiment.

In addition, in the method for processing the laminated wafer according to the third embodiment, the chamfered portion 14 is removed by applying an external force in the chamfered portion removing step 103 similarly to the second embodiment with respect to the conventional edge trimming. Therefore, there is no possibility that the disk portion 13 of the first wafer 10, that is, the region where the device is formed is etched.

### Fourth Embodiment

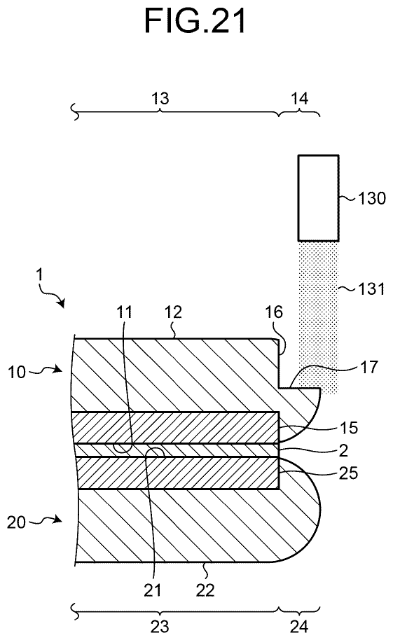

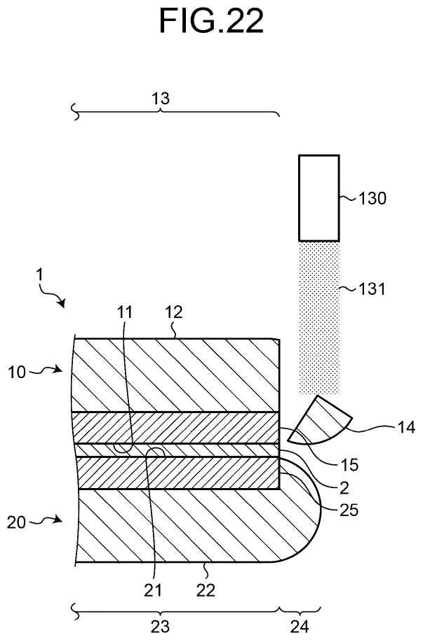

A method for processing a laminated wafer according to a fourth embodiment will be described with reference to the drawings. FIG. 21 is a side view schematically illustrating the chamfered portion removing step of the method for processing the laminated wafer according to the fourth embodiment in a partial cross section. FIG. 22 is a cross-sectional view schematically illustrating a state in which the chamfered portion is removed in the chamfered portion removing step of the method for processing the laminated wafer according to the fourth embodiment in a partial cross section. Note that, in FIGS. 21 and 22, the same parts as those of the first embodiment are denoted by the same reference signs, and description thereof is omitted.

The method for processing the laminated wafer according to the fourth embodiment is the same as that of the first embodiment except that the stepped portion 16 is formed only in the chamfered portion 14 of the first wafer 10 in the chamfered portion weakening step 102 and the chamfered portion removing step 103 is different. Note that, in the fourth embodiment, similarly to the second embodiment, in the chamfered portion weakening step 102, the stepped portion 16 is formed from the back surface 12 side of the first wafer 10 to the outer edge of the first wafer 10 and the boundary between the disk portion 13 and the chamfered portion 14 of the first wafer 10.

In the fourth embodiment, in the chamfered portion removing step 103, as illustrated in FIG. 21, a fluid jet nozzle 130 is made to face the bottom 17 of the stepped portion 16 formed in the chamfered portion 14 of the first wafer 10 of the laminated wafer 1 from the back surface 12 side, and fluid 131 is jetted from the fluid jet nozzle 130 to the bottom 17 of the stepped portion 16. In the fourth embodiment, in the chamfered portion removing step 103, the external force from the fluid 131 is concentrated on the boundary between the disk portion 13 and the chamfered portion 14 of the first wafer 10, and the chamfered portion 14 of the first wafer 10 is divided from the disk portion 13 starting from the boundary as illustrated in FIG. 22. Note that, the fluid 131 may be liquid (water), gas (air), or two fluids obtained by mixing water and air. In addition, in the fourth embodiment, the fluid 131 may be jetted from the outer peripheral side, the lower surface side, or obliquely.

The method for processing the laminated wafer according to the fourth embodiment applies an external force to the chamfered portion 14 of the first wafer 10 to separate the chamfered portion 14 from the disk portion 13 of the first wafer 10 in the chamfered portion removing step 103, so that the laminated wafer 1 can be ground and thinned without deteriorating the quality similarly to the first embodiment.

In addition, in the method for processing the laminated wafer according to the fourth embodiment, the chamfered portion 14 is removed by applying an external force in the chamfered portion removing step 103 similarly to the second embodiment with respect to the conventional edge trimming. Therefore, there is no possibility that the disk portion 13 of the first wafer 10, that is, the region where the device is formed is etched.

In addition, in the method for processing the laminated wafer according to the fourth embodiment, since the chamfered portion 14 is separated by jetting the fluid 131 in the chamfered portion removing step 103, the grinding waste generated in the chamfered portion weakening step 102 can be removed.

### Fifth Embodiment

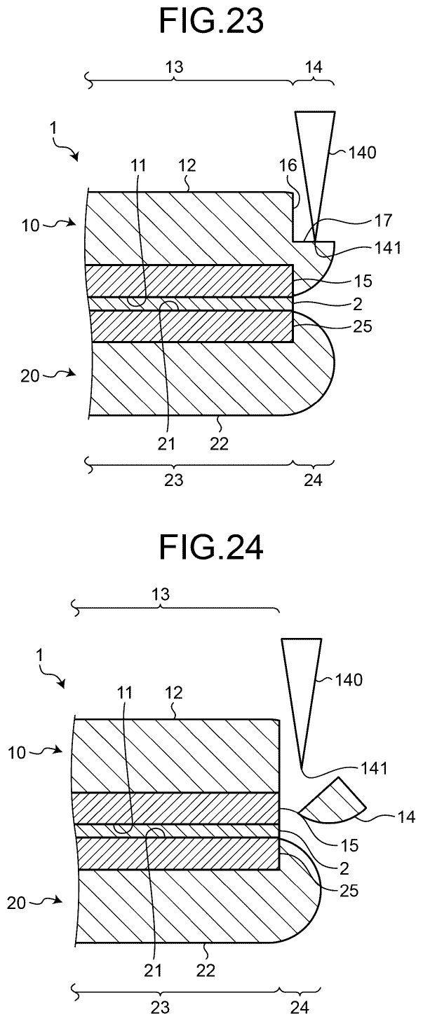

A method for processing a laminated wafer according to a fifth embodiment will be described with reference to the drawings. FIG. 23 is a side view schematically illustrating the chamfered portion removing step of the method for processing the laminated wafer according to the fifth embodiment in a partial cross section. FIG. 24 is a cross-sectional view schematically illustrating a state in which the chamfered portion is removed in the chamfered portion removing step of the method for processing the laminated wafer according to the fifth embodiment in a partial cross section. Note that, in FIGS. 23 and 24, the same parts as those of the first embodiment are denoted by the same reference signs, and description thereof is omitted.

The method for processing the laminated wafer according to the fifth embodiment is the same as that of the first embodiment except that the stepped portion 16 is formed only in the chamfered portion 14 of the first wafer 10 in the chamfered portion weakening step 102 and the chamfered portion removing step 103 is different. Note that, in the fifth embodiment, similarly to the second embodiment, in the chamfered portion weakening step 102, the stepped portion 16 is formed from the back surface 12 side of the first wafer 10 to the outer edge of the first wafer 10 and the boundary between the disk portion 13 and the chamfered portion 14 of the first wafer 10.

In the fifth embodiment, in the chamfered portion removing step 103, as illustrated in FIG. 23, a tip 141 of a pin 140 is brought into contact with the bottom 17 of the stepped portion 16 formed on the chamfered portion 14 of the first wafer 10 of the laminated wafer 1 from the back surface 12 side by the fluid jet nozzle 130, and the pin 140 is lowered. In the fifth embodiment, in the chamfered portion removing step 103, the external force from the pin 140 of the ultrasonic vibrator 120 is concentrated on the boundary between the disk portion 13 and the chamfered portion 14 of the first wafer 10, and the chamfered portion 14 of the first wafer 10 is divided from the disk portion 13 starting from the boundary as illustrated in FIG. 24. Note that, in the fifth embodiment, the pin 140 may be pressed from the outer peripheral side, the lower surface side, or obliquely.

The method for processing the laminated wafer according to the fifth embodiment applies an external force to the chamfered portion 14 of the first wafer 10 to separate the chamfered portion 14 from the disk portion 13 of the first wafer 10 in the chamfered portion removing step 103, so that the laminated wafer 1 can be ground and thinned without deteriorating the quality similarly to the first embodiment.

In addition, in the method for processing the laminated wafer according to the fifth embodiment, the chamfered portion 14 is removed by applying an external force in the chamfered portion removing step 103 similarly to the second embodiment with respect to the conventional edge trimming. Therefore, there is no possibility that the disk portion 13 of the first wafer 10, that is, the region where the device is formed is etched.

Note that, in the present disclosure, it is preferable to perform the chamfered portion weakening step 102 before performing the chamfered portion removing step 103, but it is not essential. In addition, in the present disclosure, in the chamfered portion removing step 103, in a case where a joining failure is present radially inside the chamfered portions 14 and 24 between the disk portion 13 of the first wafer 10 and the disk portion 13 of the second wafer 20 due to the shapes of the front surfaces 11 and 21 of the wafers 10 and 20, the first wafer 10 may be divided at the interface between the joining failure region and the joining region.

According to the present disclosure, it is possible to grind and thin the laminated wafer without deteriorating the quality.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A method for processing a laminated wafer in which one surface side of a first wafer having an outer peripheral edge chamfered in an arc shape and one surface side of a second wafer are joined together, the method comprising:
removing a chamfered portion by applying an external force to the chamfered portion of the first wafer and separating the chamfered portion from the first wafer; and
grinding another surface side opposite to the one surface side of the first wafer after removing the chamfered portion.

2. The method for processing the laminated wafer according to claim 1, further comprising,
before removing the chamfered portion,
grinding the chamfered portion with a grindstone to remove a part of the chamfered portion.

3. The method for processing the laminated wafer according to claim 1, wherein removing the chamfered portion includes grinding the chamfered portion with a grindstone from the other surface side of the first wafer to separate the chamfered portion from the first wafer by a load at a time of grinding.

4. The method for processing the laminated wafer according to claim 1, wherein removing the chamfered portion includes grinding the chamfered portion with a grindstone from a radially outer side of the first wafer to separate the chamfered portion from the first wafer by a load at a time of grinding.

5. The method for processing the laminated wafer according to claim 1, wherein removing the chamfered portion removing includes polishing the chamfered portion with a polishing pad from the other surface side of the first wafer to separate the chamfered portion from the first wafer by a load at a time of polishing.

6. The method for processing the laminated wafer according to claim 1, wherein removing the chamfered portion includes polishing the chamfered portion with a polishing pad from a radially outer side of the first wafer to separate the chamfered portion from the first wafer by a load at a time of polishing.

7. The method for processing the laminated wafer according to claim 1, wherein removing the chamfered portion includes applying an ultrasonic wave to the chamfered portion to separate the chamfered portion from the first wafer.
